(19) United States
(12) Patent Application Publication
(10) Pub. No.: US 2026/0065964 A1
(43) Pub. Date: Mar. 5, 2026

(54) MEMORY DEVICE

(71) Applicant: Kioxia Corporation, Tokyo (JP)

(72) Inventors: Yuka FURUKAWA, Yokohama Kanagawa (JP); Fumiyoshi MATSUOKA, Kawasaki Kanagawa (JP)

(73) Assignee: Kioxia Corporation, Tokyo (JP)

(21) Appl. No.: 19/241,007

(22) Filed: Jun. 17, 2025

(30) Foreign Application Priority Data
Aug. 30, 2024 (JP) 2024-149842

(51) Int. Cl. G11C 11/16; H10N 50/10; H10N 50/80

(52) U.S. Cl. CPC G11C 11/1673; G11C 11/161; G11C 11/1659; G11C 11/1675; H10N 50/10; H10N 50/80

(57) ABSTRACT

A second conductor is located farther in a first direction than a first conductor. A third conductor extends in the first direction, intersects with the first and second conductors. A first end of the third conductor is located farther in the first direction than a second end of the third conductor. A first memory cell is coupled to the first and third conductors. The second memory cell is coupled to the second and third conductors. A first switch is coupled to the first end. A second switch is coupled to the second end. In a case of data read from the first memory cell, the first and second switches are maintained on and off, respectively. In a case of data read from the second memory cell, the second and first witches are maintained on and off, respectively.

### CROSS-REFERENCE TO RELATED APPLICATIONS

This application is based upon and claims the benefit of priority from Japanese Patent Application No. 2024-149842, filed Aug. 30, 2024, the entire contents of which are incorporated herein by reference.

### FIELD

Embodiments described herein relate generally to a memory device.

### BACKGROUND

A memory device that stores data using an element having dynamically variable resistance is known. The memory device is required to write data in a short time.

### BRIEF DESCRIPTION OF DRAWINGS

FIG. 1 illustrates functional blocks of a memory device according to a first embodiment.

FIG. 2 is a circuit diagram of a memory cell array of the memory device of the first embodiment.

FIG. 3 is a perspective view of a part of the memory cell array of the memory device of the first embodiment.

FIG. 4 illustrates a cross section of an example of a structure of a memory cell of the memory device of the first embodiment.

FIG. 5 illustrates functional blocks and components of a part of the memory device of the first embodiment.

FIG. 6 illustrates a layout and circuit configuration of a part of the memory device of the first embodiment.

FIG. 7 illustrates components of a row selection circuit of the memory device of the first embodiment.

FIG. 8 illustrates components of a column selection circuit of the memory device of the first embodiment.

FIG. 9 illustrates an example of classification of the memory cells of the memory device of the first embodiment.

FIG. 10 is a circuit diagram of a read circuit of the memory device of the first embodiment.

FIG. 11 illustrates an example of a state during an operation of the memory device of the first embodiment.

FIG. 12 illustrates an example of a state during an operation of the memory device of the first embodiment.

FIG. 13 illustrates an example of classification of memory cells of a memory device according to a second embodiment.

FIG. 14 illustrates an example of a state during an operation of the memory device of the second embodiment.

FIG. 15 illustrates an example of a state during an operation of the memory device of the second embodiment.

FIG. 16 illustrates an example of a state during an operation of the memory device of the second embodiment.

FIG. 17 illustrates functional blocks and components of a part of the memory device of a third embodiment.

FIG. 18 illustrates components of a column selection circuit of the memory device of the third embodiment.

FIG. 19 illustrates an example of a state during an operation of the memory device of the third embodiment.

FIG. 20 illustrates an example of classification of memory cells of a memory device according to a fourth embodiment.

FIG. 21 illustrates an example of a state during an operation of the memory device of the fourth embodiment.

FIG. 22 illustrates an example of a state during an operation of the memory device of the fourth embodiment.

FIG. 23 illustrates an example of a state during an operation of the memory device of the fourth embodiment.

### DETAILED DESCRIPTION

In general, according to one embodiment, a memory device includes a first conductor, a second conductor, a third conductor, a first memory cell, a second memory cell, a first switch, and a second switch. The second conductor is located farther in a first direction than the first conductor. The third conductor extends in the first direction, intersects with the first conductor and the second conductor, and has a first end and a second end. The first end is located farther in the first direction than the second end. The first memory cell is coupled to the first conductor and the third conductor. The second memory cell is coupled to the second conductor and the third conductor. The first switch is coupled to the first end of the third conductor. The second switch is coupled to the second end of the third conductor. In a case of data read from the first memory cell, the first switch is maintained on and the second switch is maintained off. In a case of data read from the second memory cell, the second switch is maintained on and the first switch is maintained off.

Embodiments will now be described with reference to the figures. In order to distinguish components having substantially the same function and configuration in an embodiment or over different embodiments from each other, an additional numeral or letter may be added to the end of each reference numeral or letter. For an embodiment subsequent to an embodiment that has already been described, the description will concentrate mainly on the matters that constitute a difference from the already described embodiment. The entire description of a particular embodiment applies to another embodiment unless an explicit mention is made otherwise, or an obvious elimination is involved.

The specification and the claims, when mentioning that a particular (first) component is “coupled” to another (second) component, intend to cover both the form of the first component directly coupled to the second component and the form of the first component coupled to the second component via one or more components which are always or selectively conductive.

The embodiments will be described using an X-Y-Z orthogonal coordinate system. A plus direction of a vertical axis in a drawing may be referred to as an upper side, and a minus direction of the vertical axis may be referred to as a lower side. A plus direction of a horizontal axis in a drawing may be referred to as a right side, and a minus direction of the horizontal axis may be referred to as a left side. That is, in a plan view showing an X-Y plane (referred to as an X-Y plane view, the same applying hereinafter), an upper side of the X-Y plane represents a +Y direction, a lower side of the X-Y plane represents a −Y direction, a right side of the X-Y plane represents a +X direction, and a left side of the X-Y plane represents a −X direction.

### 1. First Embodiment

### 1.1. Configuration (Structure)

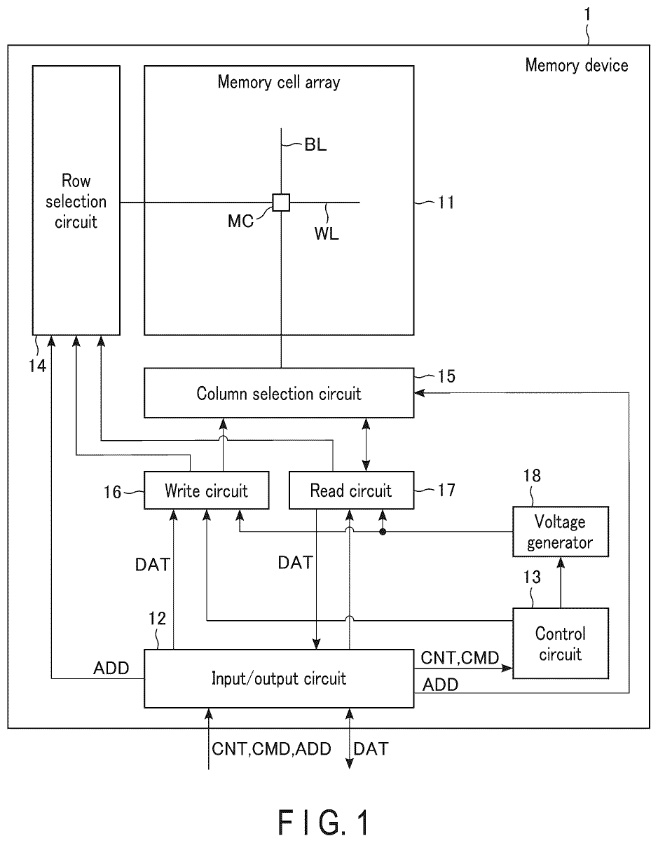

FIG. 1 illustrates functional blocks of a memory device of a first embodiment. A memory device 1 is a device that stores data. A memory device 1 stores data using a layer stack of magnets exhibiting variable resistance. As illustrated in FIG. 1, the memory device 1 includes a memory cell array 11, an input/output circuit 12, a control circuit 13, a row selection circuit 14, a column selection circuit 15, a write circuit 16, a read circuit 17, and a voltage generator 18.

The memory cell array 11 is a set of arrayed memory cells MC. The memory cells MC can store data in a nonvolatile manner. A plurality of word lines WL and a plurality of bit lines BL are located in the memory cell array 11. Each memory cell MC is coupled to a single word line WL and a single bit line BL. Each word line WL is associated with a row. Each bit line BL is associated with a column. A single memory cell MC is selected by selection of a single row and selection of a single column.

The input/output circuit 12 is a circuit that inputs and outputs data and signals. The input/output circuit 12 receives a control signal CNT, a command CMD, address information ADD, and data DAT from the outside of the memory device 1, or, in one example, from a memory controller. The input/output circuit 12 outputs the data DAT. The data DAT is write data in a case of data write in the memory device 1. The data DAT is read data in a case of data read in the memory device 1.

The voltage generator 18 is a circuit that generates voltages of various magnitudes from voltages supplied from the outside of the memory device 1. The voltage generator 18 outputs a voltage of constant magnitude used for data read. The voltage generator 18 outputs a voltage of constant magnitude used for data write.

The write circuit 16 is a circuit that controls writing of data in the memory cell MC. The write circuit 16 receives the write data DAT from the input/output circuit 12 and receives the voltage for the data write from the voltage generator 18. The write circuit 16 outputs, based on control of the control circuit 13 and the write data DAT, a voltage and a current used for data write.

The read circuit 17 is a circuit that controls reading of data from the memory cell MC. The read circuit 17 receives the voltage for data read from the voltage generator 18. The read circuit 17 determines data stored in the memory cell MC using the voltage used for the data read based on the control of the control circuit 13. The determined data is transferred to the input/output circuit 12 as the read data DAT. The read circuit 17 includes a sense amplifier.

The row selection circuit 14 is a circuit that selects a row of the memory cell MC. The row selection circuit 14 receives the address information ADD from the input/output circuit 12. The row selection circuit 14 receives the voltage for data write from the write circuit 16. The row selection circuit 14 receives the voltage for reading data from the read circuit 17. During data write, the row selection circuit 14 transfers the voltage for data write to select one or more word lines WL associated with a row specified by the received address information ADD. During data read, the row selection circuit 14 transfers the voltage for data read to select one or more word lines WL associated with the row specified by the received address information ADD.

The column selection circuit 15 is a circuit that selects a column of the memory cell MC. The column selection circuit 15 receives the address information ADD from the input/output circuit 12. The column selection circuit 15 receives the voltage for writing data from the write circuit 16. The column selection circuit 15 receives the voltage for reading data from the read circuit 17.

During writing data, the column selection circuit 15 transfers the voltage for writing data to select one or more bit lines BL associated with a column specified by the received address information ADD. During reading data, the column selection circuit 15 transfers the voltage for reading data to select the one or more bit lines BL associated with the column specified by the received address information ADD.

The control circuit 13 is a circuit that controls the operation of the memory device 1. The control circuit 13 receives the control signal CNT and the command CMD from the input/output circuit 12. The control circuit 13 controls the write circuit 16 and the read circuit 17 based on control instructed by the control signal CNT and the command CMD. Specifically, the control circuit 13 controls the write circuit 16 to supply the voltage received from the voltage generator 18 to the row selection circuit 14 and the column selection circuit 15 during writing of data in the memory cell MC. The control circuit 13 controls the read circuit 17 to supply the voltage received from the voltage generator 18 to the row selection circuit 14 and the column selection circuit 15 during reading of data from the memory cell MC.

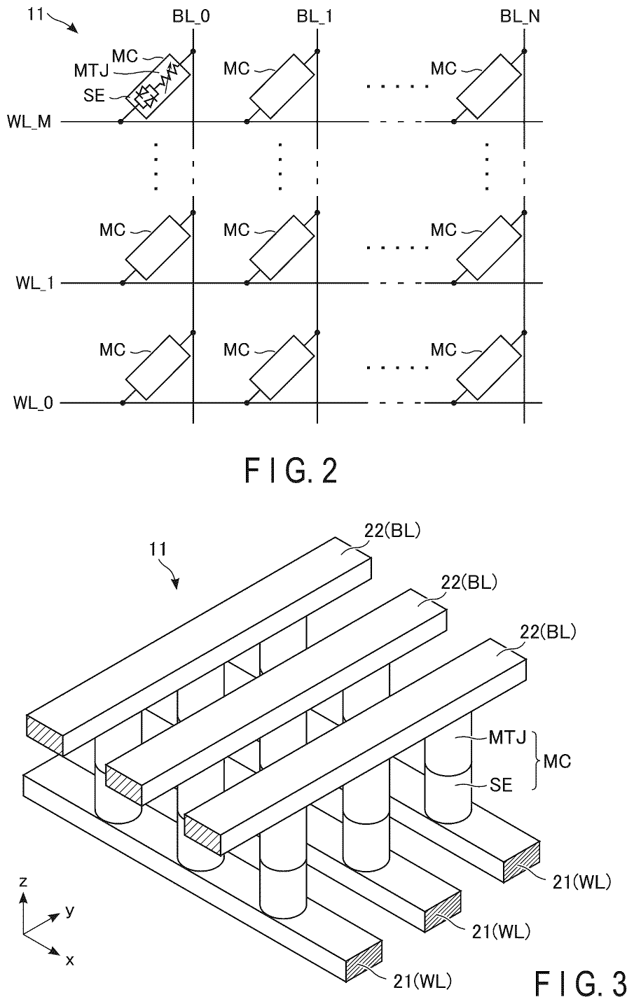

FIG. 2 is a circuit diagram of a memory cell array of the memory device of the first embodiment. As illustrated in FIG. 2, M+1 (M being a positive integer) word lines WL (i.e., WL_0, WL_1,.. and WL_M) and N+1 (N being a positive integer) bit lines BL (i.e., BL_0, BL_1,.. and BL_N) are located in the memory cell array 11.

Each memory cell MC is coupled to a single word line WL and a single bit line BL. Each memory cell MC includes a single MTJ element MTJ and a single switching element SE. In each memory cell MC, the MTJ element MTJ and the switching element SE are coupled in series. The switching element SE of each memory cell MC is coupled to a single word line WL. The MTJ element MTJ of each memory cell MC is coupled to a single bit line BL.

The MTJ element MTJ exhibits a tunnel magnetoresistive effect, and for example, is an element including a magnetic tunnel junction (MTJ). The MTJ element MTJ is also referred to as a magnetoresistive effect element MTJ. The MTJ element MTJ is a variable resistance element that can switch between a low resistance state and a high resistance state. The MTJ element MTJ can store 1-bit data using a difference between the two resistance states. In one example, the MTJ element MTJ stores “0” data with the low resistance state and “1” data with the high resistance state.

The switching element SE is an element that performs electrical coupling and decoupling between its both terminals. The switching element has two terminals. When a voltage applied between the two terminals is lower than a first threshold, the switching element SE is in a high resistance state, for example, an electrically non-conductive state (or, OFF state). When the voltage applied between the two terminals rises to the first threshold or higher, the switching element SE enters a low resistance state, for example, an electrically conductive state (or, ON state). When the voltage applied between the two terminals of the switching element SE in the low resistance state falls to a second threshold or lower, the switching element SE enters the high resistance state. The switching element SE has the function of switching between the high resistance state and the low resistance state based on the magnitude of the voltage applied in a first direction, and the same function also in a second direction opposite to the first direction. That is, the switching element SE is a bidirectional switching element. With ON or OFF state of the switching element SE, the presence or absence of supply of a current to the MTJ element MTJ coupled to the switching element SE, that is, selection or non-selection of the MTJ element MTJ can be controlled.

FIG. 3 is a perspective view of a part of the memory cell array of the memory device of the first embodiment. As illustrated in FIG. 3, a plurality of conductors 21 and a plurality of conductors 22 are provided.

The conductors 21 each have a linear shape extending along an x axis. The conductors 21 are aligned along a y axis. The y axis is perpendicular to the x axis. Each of the conductors 21 functions as a single word line WL.

The conductors 22 are located above the conductors 21 on a z axis. The z axis is perpendicular to the x axis and the y axis. The conductors 22 each have a linear shape, extend along the y axis, and are aligned along the x axis. Each of the conductors 22 functions as a single bit line BL.

One memory cell MC is provided at each of intersections of the conductors 21 and the conductors 22. Each memory cell MC includes a structure functioning as the switching element SE and a structure functioning as the MTJ element MTJ. Each of the structure functioning as the switching element SE and the structure functioning as the MTJ element MTJ includes one or more layers. In one example, the structure functioning as the MTJ element MTJ is located on the upper surface of the structure functioning as the switching element SE. The lower surface of the memory cell MC is in contact with the upper surface of one conductor 21. The upper surface of the memory cell MC is in contact with the lower surface of one conductor 22.

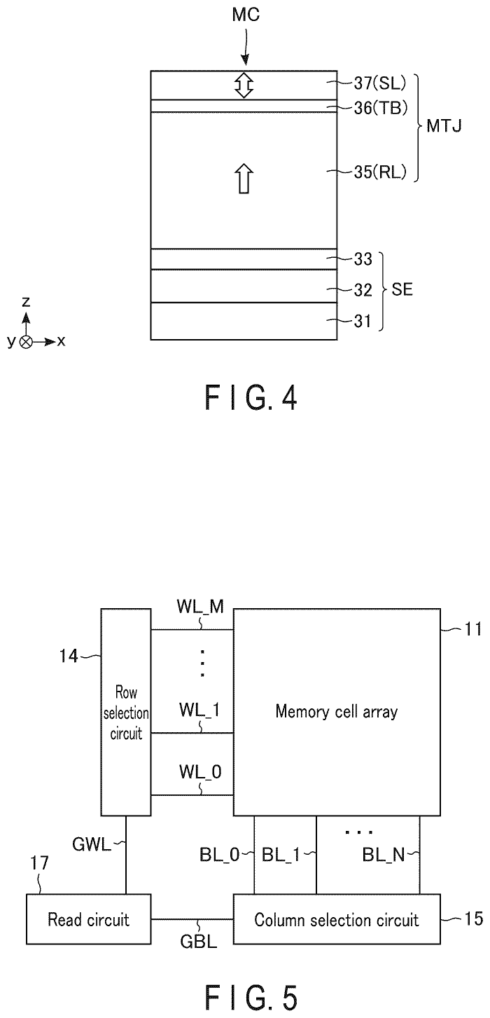

FIG. 4 illustrates a cross section of an exemplary structure of the memory cell of the memory device of the first embodiment. As illustrated in FIG. 4, the switching element SE includes a variable resistance material 32. The variable resistance material 32 is a material exhibiting dynamically variable resistance, and, in one example, has a layer shape. The variable resistance material 32 is a switching element between its two terminals where a first terminal of the two terminals is one of the upper surface and the lower surface of the variable resistance material 32, and a second terminal of the two terminals is the other of the upper surface and the lower surface of the variable resistance material 32. While a voltage applied between the two terminals is lower than a first threshold (threshold voltage Vth), the variable resistance material 32 is in a “high resistance” state, for example, an electrically non-conductive state. When the voltage applied between the two terminals rises to the first threshold or higher, the variable resistance material enters a “low resistance” state, for example, an electrically conductive state. When the voltage applied between the two terminals of the variable resistance material 32 in the low resistance state falls to a second threshold or lower, the variable resistance material enters the high resistance state. The variable resistance material 32 includes an insulator and a dopant introduced into the insulator by ion implantation. In one example, the insulator includes an oxide, SiO₂, or a material consisting substantially of SiO₂. In one example, the dopant includes arsenic (As) and germanium (Ge).

In the present embodiment, the variable resistance material 32 having the above-described composition has been described, but the present invention is not limited to this composition.

The description “consisting (or formed) substantially of” and similar terms are meant to permit a component “consisting substantially of” something to contain unintended impurities.

The switching element SE can further include a lower electrode 31 and an upper electrode 33. FIG. 4 illustrates such an example. The variable resistance material 32 is located on an upper surface of the lower electrode 31, and the upper electrode 33 is located on an upper surface of the variable resistance material 32.

The MTJ element MTJ includes a ferromagnetic layer 35, an insulating layer 36, and a ferromagnetic layer 37. As an example, as illustrated in FIG. 4, the insulating layer 36 is located on an upper surface of the ferromagnetic layer 35, and the ferromagnetic layer 37 is located on an upper surface of the insulating layer 36.

The ferromagnetic layer 35 is a layer of a material exhibiting ferromagnetism. The ferromagnetic layer 35 has an easy magnetization axis in a direction penetrating through interfaces among the ferromagnetic layer 35, the insulating layer 36, and the ferromagnetic layer 37, or, in one example, in a direction at an angle of 45° through 90° to the interfaces, or in a direction orthogonal to the interfaces. A magnetization direction of the ferromagnetic layer 35 is intended to remain unchanged even by reading and writing of data in the memory cell MC. The ferromagnetic layer 35 can function as a so-called reference layer. The ferromagnetic layer 35 may include a plurality of layers. Hereinafter, the ferromagnetic layer 35 may be referred to as reference layer 35.

The insulating layer 36 is a layer of an insulator. The insulating layer 36 includes or consists substantially of magnesium oxide (MgO) in one example, and functions as a so-called tunnel barrier.

The ferromagnetic layer 37 is a layer of a material exhibiting ferromagnetism. In one example, the ferromagnetic layer 37 includes or consists substantially of cobalt iron boron (CoFeB) or iron boride (FeB). The ferromagnetic layer 37 has an easy magnetization axis in a direction penetrating through interfaces among the ferromagnetic layer 35, the insulating layer 36, and the ferromagnetic layer 37, or in a direction at an angle of 45° through 90° to the interfaces or in a direction orthogonal to the interfaces. A magnetization direction of the ferromagnetic layer 37 is variable by writing data to the memory cell MC, and the ferromagnetic layer 37 can function as a so-called storage layer. Hereinafter, the ferromagnetic layer 37 may be referred to as storage layer 37.

When the magnetization direction of the storage layer 37 is parallel to the magnetization direction of the reference layer 35, the MTJ element MTJ has a low resistance. When the magnetization direction of the storage layer 37 is antiparallel to the magnetization direction of the reference layer 35, the MTJ element MTJ has a resistance higher than a resistance in the case in which the magnetization direction of the storage layer 37 and the magnetization direction of the reference layer 35 are parallel. Hereinafter, the state in which the magnetization direction of the ferromagnetic layer 37 of an MTJ element MTJ is parallel to the magnetization of the reference layer 35 may be referred to as the MTJ element MTJ “in a parallel state” or “in a P state”. The state in which the magnetization direction of the ferromagnetic layer 37 of an MTJ element MTJ is antiparallel to the magnetization of the reference layer 35 may be referred to as the MTJ element MTJ “in an antiparallel state” or “in an AP state”.

When a current having a magnitude equal to or larger than a magnitude of a current Icp flows from the storage layer 37 toward the reference layer 35, the magnetization direction of the storage layer 37 becomes parallel to the magnetization direction of the reference layer 35.

When a current having a magnitude equal to or larger than a magnitude of a current Icap flows from the reference layer 35 toward the storage layer 37, the magnetization direction of the storage layer 37 becomes antiparallel to the magnetization direction of the reference layer 35.

The MTJ element MTJ may include further layers.

FIG. 5 illustrates functional blocks and components of a part of the memory device of the first embodiment. As illustrated in FIG. 5, the read circuit 17 is coupled to a global word line GWL and a global bit line GBL.

The global word line GWL is coupled to the row selection circuit 14. The row selection circuit 14 couples the global word line GWL to a single word line WL selected by the address information ADD.

The global bit line GBL is coupled to the column selection circuit 15. The column selection circuit 15 couples the global bit line GBL to a single bit line BL selected by the address information ADD.

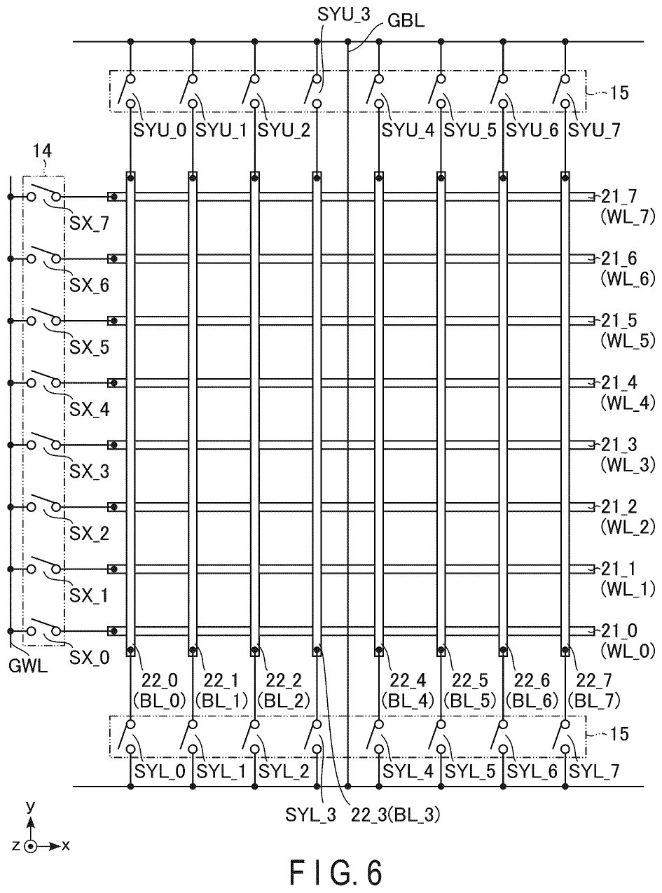

FIG. 6 illustrates a layout and circuit configuration of a part of the memory device of the first embodiment. FIG. 6 illustrates a layout of the conductors 21 and 22 and switches SX, SYL, and SYU to be described later, and illustrates a circuit configuration of other components.

FIG. 6 illustrates an example of eight conductors 21 and eight conductors 22, that is, an example of M=N=7. The drawings following FIG. 6 and the description hereinafter are based on this example.

As illustrated in FIG. 6, for all cases where α is 0 or more and M or less, the larger α a conductor 21_α functioning as a word line WL_α has, the farther in the Y direction the conductor_α is located. For all cases where β is 0 or more and N or less, the larger β a conductor 22_β functioning as a bit line BL_β has, the farther in the X direction the conductor_β is located.

The row selection circuit 14 includes M+1 switches SX, that is, eight switches SX_0 to SX_7 based on the current example. The switches SX_0 to SX_7 are located farther in the −X direction than the conductors 21. For all cases where α is 0 or more and 7 or less, one end of a switch SX_α is coupled to an end of the conductor 21_α on a −X direction side by an interconnect (or conductor). The other end of each of the switches SX_0 to SX_7 is coupled to the global word line GWL via an interconnect. Examples of each switch SX include an n-type metal oxide semiconductor field effect transistor (MOSFET), a p-type MOSFET, and p-type and n-type MOSFETs coupled in parallel.

The column selection circuit 15 includes N+1 switches SYL, that is, eight switches SYL_0 to SYL_7 based on the current example. The switches SYL_0 to SYL_7 are located farther in the −Y direction than the conductors 21. For all cases where β is 0 or more and 7 or less, one end of a switch SYL_β is coupled to an end of the conductor 22_β on a −Y direction side by an interconnect (or conductor). The other end of each of the switches SYL_0 to SYL_7 is coupled to the global bit line GBL via an interconnect.

Examples of each switch SYL include n-type MOSFET, the p-type MOSFET, and the p-type and n-type MOSFETs coupled in parallel.

The column selection circuit 15 includes N+1 switches SYU, that is, eight switches SYU_0 to SYU_7 based on the current example. The switches SYU_0 to SYU_7 are located farther in the Y direction than the conductors 21. For all cases where β is 0 or more and 7 or less, one end of a switch SYU_β is coupled to the end of the conductor 22_β on a Y direction side by an interconnect (or conductor). The other end of each of the switches SYU_0 to SYU_7 is coupled to the global bit line GBL via an interconnect. Examples of each switch SYU include the n-type MOSFET, the p-type MOSFET, and the p-type and n-type MOSFETs coupled in parallel.

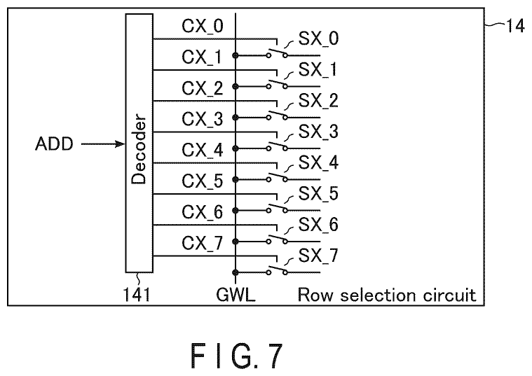

FIG. 7 illustrates components of the row selection circuit 14 of the memory device of the first embodiment. As illustrated in FIG. 7, the switches SX_0 to SX_7 receive signals CX_0 to CX_7, respectively, at control terminals (or gate electrodes). The switches SX_0 to SX_7 remain on or off based on the signals CX_0 to CX_7, respectively. While the signals CX_0 to CX_7 have logic at an assertion level (or an asserted logic level), the respective switches SX_0 to SX_7 remain on. Assertion level logic for n-type MOSFETs is a high level. Assertion level logic for p-type MOSFETs is a low level.

The signals CX_0 to CX_7 are supplied from a decoder (decoder circuit) 141 in the row selection circuit 14. The decoder 141 receives the address information ADD and decodes the address information ADD. The decoder 141 outputs the signals CX_0 to CX_7 having logic levels based on the result of decoding.

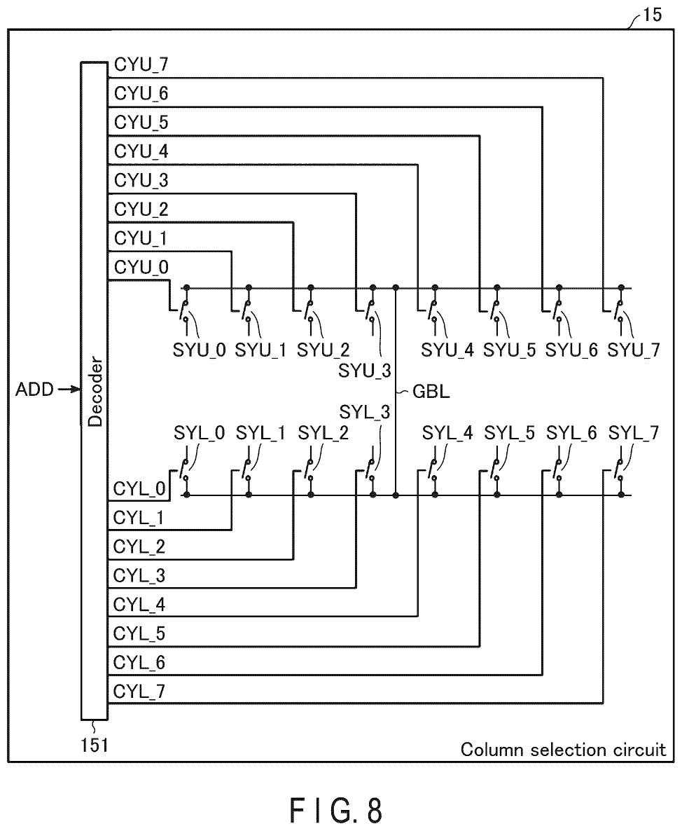

FIG. 8 illustrates components of the column selection circuit of the memory device of the first embodiment. As illustrated in FIG. 8, the switches SYL_0 to SYL_7 receive signals CYL_0 to CYL_7, respectively, at control terminals (or gate electrodes). The switches SYL_0 to SYL_7 remain on or off based on the signals CYL_0 to CYL_7, respectively. While the signals CYL_0 to CYL_7 have assertion level logic, the respective switches SYL_0 to SYL_7 are on.

The switches SYU_0 to SYU_7 receive signals CYU_0 to CYU_7, respectively, at control terminals (or gate electrodes). The switches SYU_0 to SYU_7 remain on or off based on the signals CYU_0 to CYU_7, respectively. While the signals CYU_0 to CYU_7 have assertion level logic, the respective switches SYU_0 to SYU_7 are on.

The signals CYL_0 to CYL_7 and CYU_0 to CYU_7 are supplied from a decoder (decoder circuit) 151 in the column selection circuit 15. The decoder 151 receives the address information ADD and decodes the address information ADD. The decoder 151 outputs the signals CYL_0 to CYL_7 and CYU_0 to CYU_7 having logic levels based on the result of decoding.

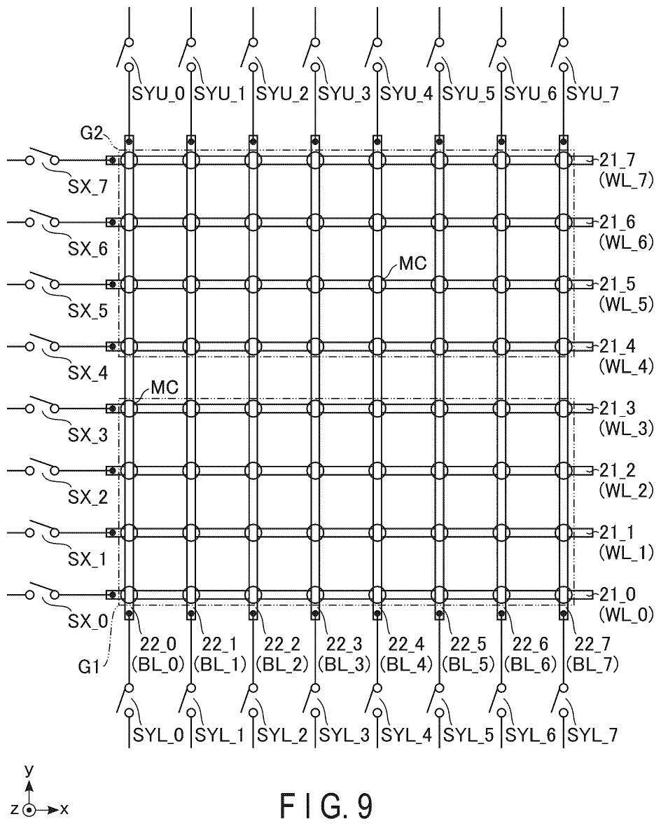

FIG. 9 illustrates an example of classification of the memory cells of the memory device of the first embodiment. The memory cells MC are classified into two groups. For example, in a case where M/2 conductors 21 are arranged in the positive direction and M/2 conductors 21 are arranged in the negative direction from the center of the conductor 22 on the y axis, the memory cell MC coupled to the conductor 21_α belongs to a group G1 for all cases where α is 0 or more and less than (M+1)/2. In other words, for all cases where β is 0 or more and N or less, in a case where a distance of a current path from a certain memory cell MC to the switch SYL_β via the current path including a part of the conductor 22_β is shorter than a distance of a current path from the memory cell MC to the switch SYU_β via the current path including a part of the conductor 22_β, the memory cell MC belongs to the group G1. Based on the current example, the memory cell MC coupled to any of the conductors 21_0, 21_1, 21_2, and 21_3 belongs to the group G1. That is, the conductors 21_0, 21_1, 21_2, and 21_3 are closer to an end (or lower end) of the conductor 22 on the −Y direction side than to an end (or upper end) of the conductor 22 on the Y direction side.

For all cases where α is (M+1)/2 or more and M or less, the memory cell MC coupled to the conductor 21_α belongs to a group G2. In other words, for all cases where β is 0 or more and N or less, in a case where a distance of a current path from a certain memory cell MC to the switch SYU_β via the current path including a part of the conductor 22_β is shorter than a distance of a current path from the memory cell MC to the switch SYL_β via the current path including a part of the conductor 22_β, the memory cell MC belongs to the group G2. Based on the current example, the memory cell MC coupled to any of the conductors 21_4, 21_5, 21_6, and 21_7 belongs to the group G2. That is, the conductors 21_4, 21_5, 21_6, and 21_7 are closer to the upper end than to the lower end of the conductor 22.

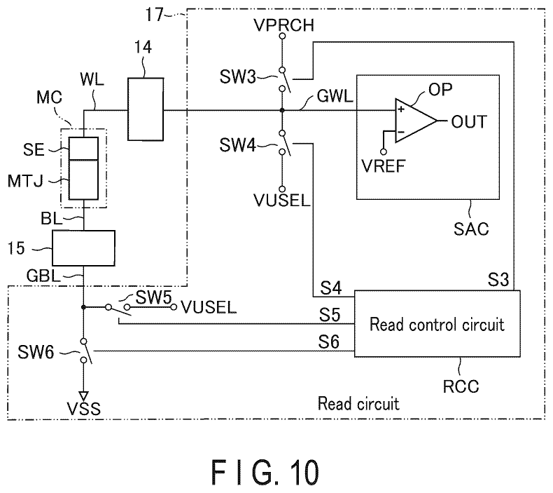

FIG. 10 is a circuit diagram of the read circuit of the memory device of the first embodiment. FIG. 10 illustrates a state in which a certain memory cell MC is selected as a representative. That is, as described above with reference to FIG. 1, a single word line WL is brought into a selected state by the row selection circuit 14, and a single bit line BL is brought into a selected state by the column selection circuit 15. In this state, one memory cell MC coupled to the word line WL in the selected state and the bit line BL in the selected state is brought into a selected state, and data is read from the memory cell MC in the selected state. The word line WL, the bit line BL, and the memory cell MC illustrated in FIG. 10 are in the selected state.

As illustrated in FIG. 10, the read circuit 17 is coupled to the global word line GWL and the global bit line GBL. The read circuit 17 includes a sense amplifier circuit SAC, switches SW3, SW4, SW5, and SW6, and a read control circuit RCC. Examples of the switches SW3, SW4, SW5, and SW6 include the n-type MOSFET, the p-type MOSFET, and the p-type and n-type MOSFETs coupled in parallel.

The switch SW3 is coupled between a node that receives a precharge voltage VPRCH of a constant magnitude and the global word line GWL. The node that receives the precharge voltage VPRCH functions as a node that supplies the precharge voltage VPRCH. In one example, the precharge voltage VPRCH is supplied from the voltage generator 18. The precharge voltage VPRCH is higher than a ground voltage VSS. The switch SW3 is on while receiving a signal S3 of the assertion level logic.

The switch SW4 is coupled between the global word line GWL and a node that receives a non-selection voltage VUSEL of a constant magnitude. The node that receives the non-selection voltage VUSEL functions as a node that supplies the non-selection voltage VUSEL. In one example, the non-selection voltage VUSEL is supplied from the voltage generator 18. The non-selection voltage VUSEL has a magnitude between that of the ground voltage VSS and that of the precharge voltage VPRCH, and a potential difference between the precharge voltage VPRCH and the non-selected voltage VUSEL and a potential difference between the non-selection voltage VUSEL and the ground voltage VSS are smaller than a first threshold of the switching element SE. In one example, the non-selection voltage VUSEL has half the magnitude of the precharge voltage VPRCH. The switch SW4 is on while receiving a signal S4 of the assertion level logic.

The sense amplifier circuit SAC outputs data determined to be stored in a selected memory cell MC whose data is to be read based on a voltage on the global word line GWL. In one example, the sense amplifier circuit SAC includes an operational amplifier OP. A non-inverting input of the operational amplifier OP is coupled to the global word line GWL. An inverting input of the operational amplifier OP receives a reference voltage VREF. In one example, the reference voltage VREF has a potential between the magnitude of a high hold voltage VhdH and the magnitude of a low hold voltage VhdL. The high hold voltage VhdH is a terminal voltage of the memory cell MC including the MTJ element MTJ in the high resistance state. The low hold voltage VhdL is a terminal voltage of the memory cell MC including the MTJ element MTJ in the low resistance state.

The switch SW5 is coupled between the global bit line GBL and a node that receives the non-selection voltage VUSEL. The switch SW5 is on while receiving a signal S5 of the assertion level logic.

The switch SW6 is coupled between the global bit line GBL and a node that receives the ground voltage VSS. The switch SW6 is on while receiving a signal S6 of the assertion level logic.

The read control circuit RCC outputs the signals S4 to S6.

### 1.2. Operation

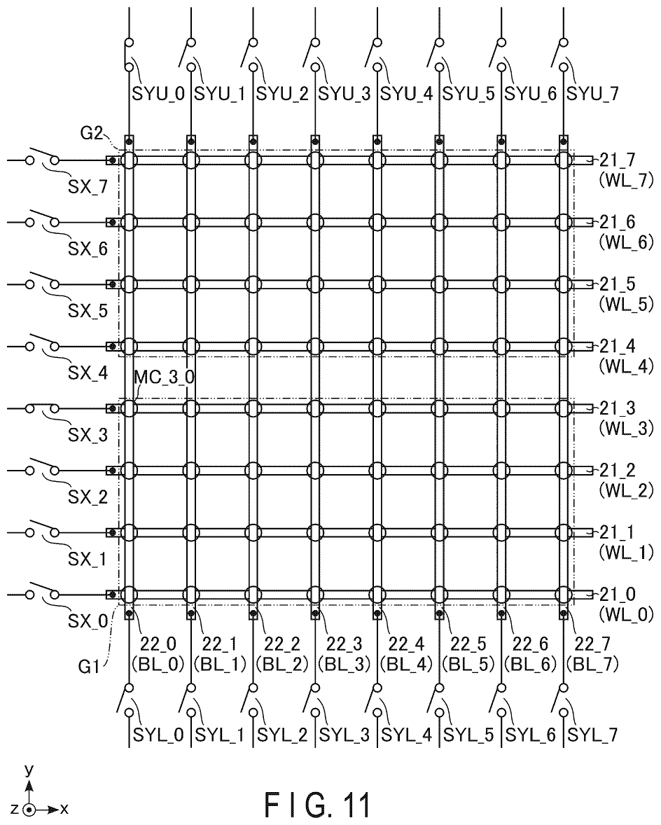

FIG. 11 illustrates an example of a state during an operation of the memory device of the first embodiment.

FIG. 11 illustrates a state during which data is being read from a memory cell MC belonging to the group G1, and, as an example, illustrates a state during which data is being read from a memory cell MC_3_0. A memory cell MC_p_q is a memory cell MC coupled to a word line WL_p and a bit line BL_q. Hereinafter, a data read target memory cell MC may be referred to as a selected memory cell MC. The word line WL and the bit line BL coupled to the selected memory cell MC may be referred to as a selected word line WL and a selected bit line BL, respectively. A word line WL other than the selected word line WL may be referred to as a non-selected word line WL. A bit line BL other than the selected bit line BL may be referred to as a non-selected bit line BL.

The switch SX coupled to the selected word line WL (or the conductor 21 functioning as the selected word line WL) is maintained on, and the switch SX coupled to the non-selected word line WL (or the conductor 21 functioning as the non-selected word line WL) is maintained off. In the example of FIG. 11, the switch SX_3 is maintained on, and all of the switches SX except for the switch SX_3 are maintained off.

In a case where the data read target memory cell MC belongs to the group G1, of the switches SYL and SYU coupled to the selected bit line BL (or the conductor 22 functioning as the selected bit line BL), the switch SYU is maintained on and the switch SYL is maintained off. The switches SYL and SYU coupled to the non-selected bit line BL (the conductor 22 functioning as the non-selected bit line BL) are maintained off. In the example of FIG. 11, the switch SYU_0 is maintained on, and all of the switches SYU except for the switch SYU_0 and all of the switches SYL are maintained off.

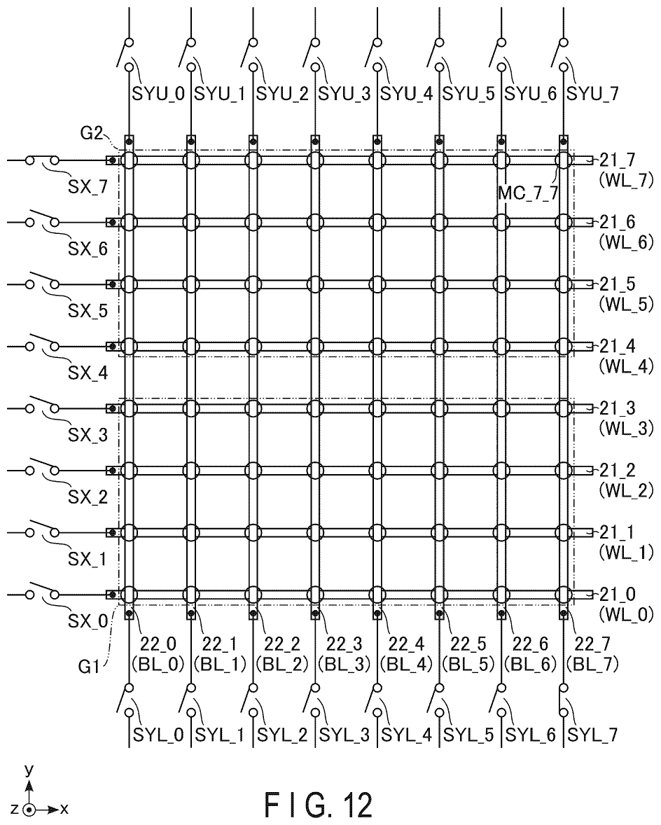

FIG. 12 illustrates an example of a state during an operation of the memory device of the first embodiment. FIG. 12 illustrates a state during which data is being read from a memory cell MC belonging to the group G2, and, as an example, illustrates a state during which data is being read from the memory cell MC_7_7.

The switch SX coupled to the selected word line WL is maintained on, and the switch SX coupled to the non-selected word line WL is maintained off. In the example of FIG. 12, the switch SX_7 is maintained on, and all of the switches SX except for the switch SX_7 are maintained off. In a case where the data read target memory cell MC belongs to the group G2, of the switches SYL and SYU coupled to the selected bit line BL, the switch SYL is maintained on and the switch SYU is maintained off. The switches SYL and SYU coupled to the non-selected bit line BL are maintained off. In the example of FIG. 12, the switch SYL_7 is maintained on, and all of the switches SYL except for the switch SYL_7 and all of the switches SYU are maintained off.

A data read operation is performed while the selected memory cell MC is coupled to the global word line GWL and the global bit line GBL according to the rules described above with reference to FIGS. 11 and 12. The read operation can be performed in any form. Hereinafter, an example of the read operation will be described. That is, first, the voltage VUSEL is applied to the global word line GWL and the global bit line GBL. This is performed by maintaining the switches SW3 and SW6 off and maintaining the switches SW4 and SW5 on.

While the non-selection voltage VUSEL is applied to the global bit line GBL, the precharge voltage VPRCH is applied to the global word line GWL. This is performed by maintaining the switch SW4 off and maintaining the switch SW3 on. Next, by maintaining the switch SW3 off, the global word line GWL is maintained in an electrically floating state.

While the global word line GWL is electrically floating, the ground voltage VSS is applied to the global bit line GBL. This is performed by maintaining the switch SW5 off and maintaining the switch SW6 on. As a result, a difference between the potential of the selected word line WL and the selected bit line BL reaches the threshold voltage Vth of the switching element SE of the selected memory cell MC. As a result, the switching element SE of the selected memory cell MC is turned on. Thus, a cell current flows from the selected word line WL toward the selected bit line BL via the selected memory cell MC, and the potential of the selected word line WL decreases. In a case where the MTJ element MTJ of the selected memory cell MC is in the high resistance state due to the decrease in the potential of the selected word line WL, when the terminal voltage of the selected memory cell MC becomes the high hold voltage VhdH, the switching element SE of the selected memory cell MC is turned off. On the other hand, in a case where the MTJ element MTJ of the selected memory cell MC is in the low resistance state, when the terminal voltage of the selected memory cell MC becomes the low hold voltage VhdL, the switching element SE of the selected memory cell MC is turned off. Therefore, the global word line GWL has a potential of a magnitude based on the resistance state of the MTJ element MTJ of the selected memory cell MC. The potential is used by the read circuit 17 to determine the data stored in the selected memory cell MC.

### 1.3. Advantages (Advantageous Effects)

According to the memory device of the first embodiment, as described below, it is possible to suppress erroneous write of data and breakdown of the memory cell MC.

It is conceivable that only a set of the switches SYL_0 to SYL_7 is provided without providing a set of the switches SYU_0 to SYU_7. In this case, the length of the current path including the memory cell MC greatly differs depending on the position of the memory cell MC. That is, the current path including a memory cell MC located far from both the row selection circuit 14 and the column selection circuit 15 (for example, the memory cell MC_7_7) is long, and thus the resistance of the current path is large. On the other hand, the current path including a memory cell MC located close to both the row selection circuit 14 and the column selection circuit 15 (for example, the memory cell MC_0_0) is short, and thus the resistance of the current path is small. A difference between the longest current path and the shortest current path is large. In this case, since the charge charged by the precharge voltage VPRCH is the same even if the current path is different, the charge is discharged with a small parasitic resistance during data read from the memory cell MC included in the short current path, and thus a cell current with a large peak flows. Depending on the magnitude of the peak of the cell current, the resistance state of the MTJ element MTJ of the memory cell MC included in the short current path may change, and thus erroneous write of data, or read disturb may occur. Furthermore, depending on the magnitude of the cell current, the breakdown of the memory cell MC may occur.

According to the first embodiment, the switches SYU and SYL are coupled to one end and the other end of each conductor 22 (or bit line BL), respectively, and during data read, of the switches SYU and SYL coupled to the selected bit line BL, one farther from the selected memory cell MC is maintained on, and the other is maintained off. That is, even if each conductor 21 can be coupled to the global bit line GBL via the closer one of the switches SYU and SYL, each conductor 21 is coupled to the global bit line GBL via the farther one. Therefore, the short current path is not used even if it can be formed. This leads to a suppression in a difference between the length of the longest current path used (for example, the case of the selected memory cell MC_7_7) and the length of the shortest current path used (for example, the case of the selected memory cell MC_3_0). Since the difference between the longest and shortest current paths is small, a difference between the resistance of the longest current path and the resistance of the shortest current path is small. Therefore, even with the same precharge voltage VPRCH, a difference in the magnitude of the peak of the cell current based on the difference in the current path is suppressed. As a result, erroneous data write, or read disturb to the memory cell MC and the breakdown of the memory cell are suppressed.

### 2. Second Embodiment

The second embodiment is different from the first embodiment in terms of classification of the memory cells MC.

### 2.1. Configuration

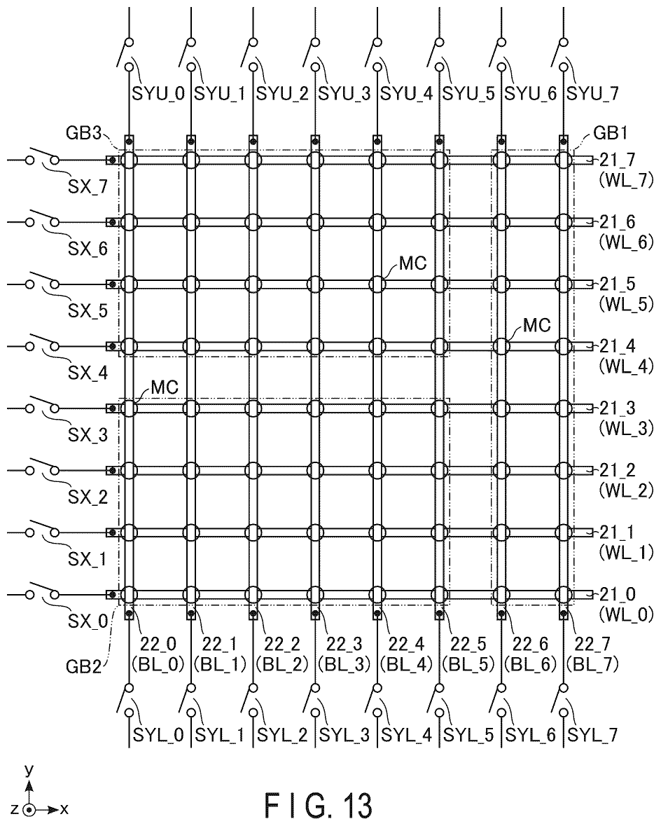

FIG. 13 illustrates an example of classification of the memory cells of a memory device of a second embodiment. The emory cells MC are classified into three groups. For all cases where β is P or more and N or less, a memory cell MC coupled to a conductor 22_β belongs to a group GB1. In other words, a memory cell MC located far from a switch SX belongs to the group GB1. An example of P is a minimum integer greater than or equal to (N+1)/2. Another example of P is a minimum integer greater than or equal to (N+1)×2/3. Based on the current example, P is 6, and the following description is based on this example. Based on the current example, the memory cell MC coupled to any of the conductor 22_6 and the conductor 22_7 belongs to the group GB1.

For all cases where β is 0 or more and less than P and all cases where α is 0 or more and less than (M+1)/2, a memory cell MC coupled to the conductor 22_β and a conductor 21_α belongs to a group GB2. In other words, for all cases where a memory cell MC is located close to the switch SX and β is 0 or more and less than P, in a case where a distance of the current path from a certain memory cell MC to a switch SYL_β via the current path including a part of the conductor 22_β (or bit line BL_β) is shorter than a distance of the current path from the memory cell MC to a switch SYU_β via the current path including a part of the conductor 22_β, the memory cell MC belongs to the group GB2. Based on the current example, the memory cell MC coupled to any of conductors 22_0, 22_1, 22_2, 22_3, 22_4, and 22_5 and coupled to any of the conductors 21_0, 21_1, 21_2, and 21_3 belongs to the group GB2.

For all cases where β is 0 or more and less than P and all cases where α is (M+1)/2 or more and M or less, a memory cell MC coupled to the conductor 22_β and the conductor 21_α belongs to a group GB3. In other words, for all cases where a memory cell MC is located close to the switch SX and β is 0 or more and less than P, in a case where a distance of the current path from a certain memory cell MC to the switch SYU_β via the current path including a part of the conductor 22_β (or bit line BL_β) is shorter than a distance of the current path from the memory cell MC to the switch SYL_β via the current path including a part of the conductor 22_β, the memory cell MC belongs to the group GB3. Based on the current example, the memory cell MC coupled to any of the conductors 22_0, 22_1, 22_2, 22_3, 22_4, and 22_5 and coupled to any of conductors 21_4, 21_5, 21_6, and 21_7 belongs to the group GB3.

### 2.2 Operation

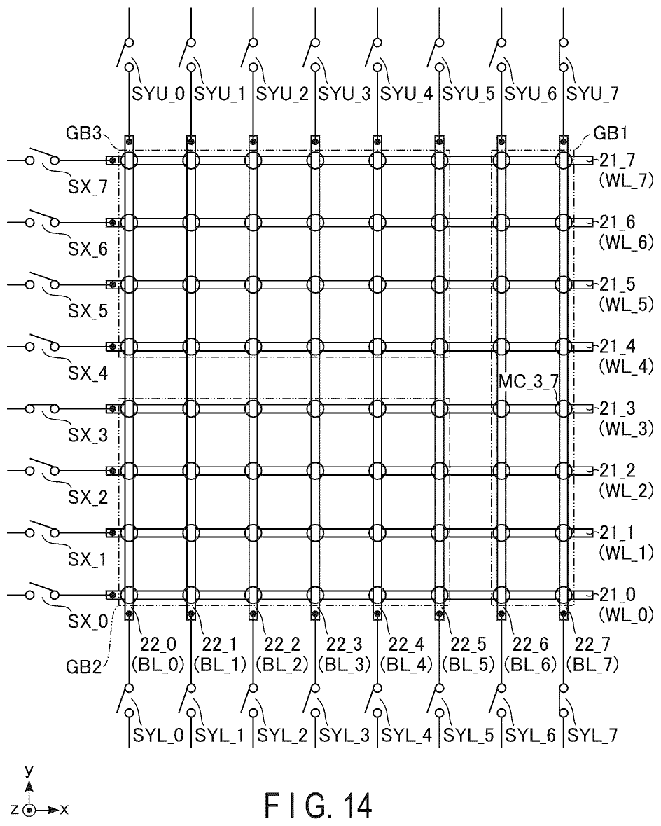

FIG. 14 illustrates an example of a state during an operation of the memory device of the second embodiment. FIG. 14 illustrates a state during which data is being read from a memory cell MC belonging to the group GB1, and, as an example, illustrates a state during which data is being read from the memory cell MC_3_7.

The switch SX coupled to the selected word line WL is maintained on, and the switch SX coupled to the non-selected word line WL is maintained off. In the example of FIG. 14, the switch SX_3 is maintained on, and all of the switches SX except for the switch SX_3 are maintained off.

In a case where a data read target memory cell MC belongs to the group GB1, both the switches SYL and SYU coupled to the selected bit line BL are maintained on. The switches SYL and SYU coupled to the non-selected bit line BL are maintained off. In the example of FIG. 14, the switch SYL_7 and a switch SYU_7 are maintained on, and all of the switches SYL except for the switch SYL_7 and all of the switches SYU except for the switch SYU_7 are maintained off.

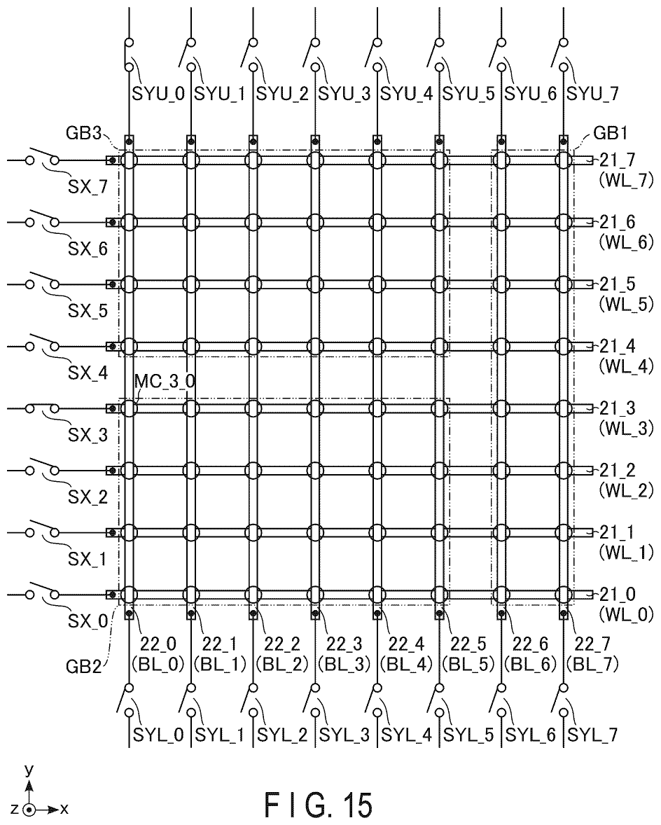

FIG. 15 illustrates an example of a state during an operation of the memory device of the second embodiment. FIG. 15 illustrates a state during which data is being read from a memory cell MC belonging to the group GB2, and, as an example, illustrates a state during which data is being read from the memory cell MC_3_0.

The switch SX coupled to the selected word line WL is maintained on, and the switch SX coupled to the non-selected word line WL is maintained off. In the example of FIG. 15, the switch SX_3 is maintained on, and all of the switches SX except for the switch SX_3 are maintained off.

In a case where a data read target memory cell MC belongs to the group GB2, of the switches SYL and SYU coupled to the selected bit line BL, the switch SYU is maintained on and the switch SYL is maintained off. The switches SYL and SYU coupled to the non-selected bit line BL are maintained off. In the example of FIG. 15, a switch SYU_0 is maintained on, and all of the switches SYU except for the switch SYU_0 and all of the switches SYL are maintained off.

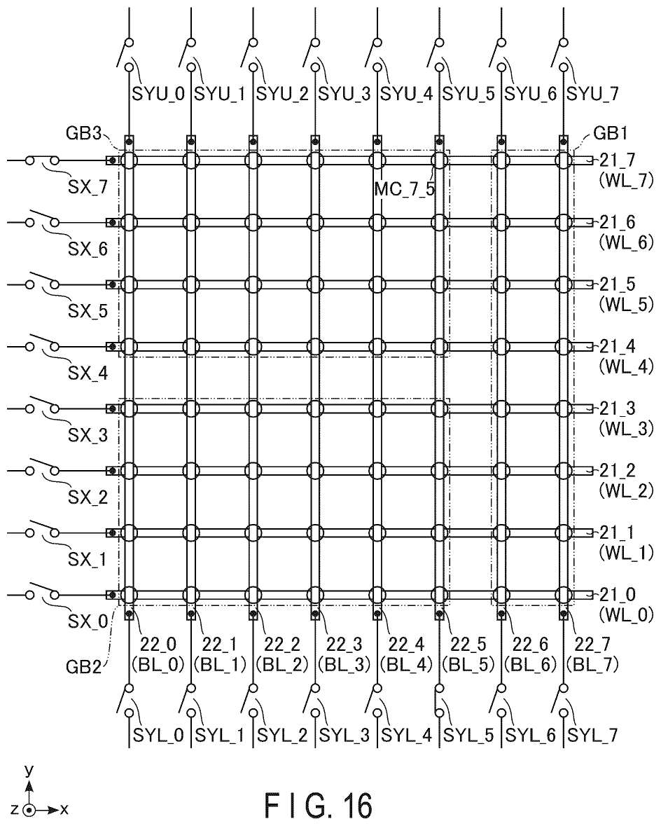

FIG. 16 illustrates an example of a state during an operation of the memory device of the second embodiment. FIG. 16 illustrates a state during which data is being read from a memory cell MC belonging to the group GB3, and, as an example, illustrates a state during which data is being read from the memory cell MC_7_5.

The switch SX coupled to the selected word line WL is maintained on, and the switch SX coupled to the non-selected word line WL is maintained off. In the example of FIG. 16, the switch SX_7 is maintained on, and all of the switches SX except for the switch SX_7 are maintained off.

In a case where a data read target memory cell MC belongs to the group GB3, of the switches SYL and SYU coupled to the selected bit line BL, the switch SYL is maintained on and the switch SYU is maintained off. The switches SYL and SYU coupled to the non-selected bit line BL are maintained off. In the example of FIG. 16, the switch SYL_5 is maintained on, and all of the switches SYL except for the switch SYL_5 and all of the switches SYU are maintained off.

The read operation in a state where the memory cell MC is selected is the same as that in the first embodiment.

### 2.3. Advantages

The memory cell MC located far from the switch SX has a large resistance due to the conductor 21. According to the second embodiment, as in the first embodiment, the switches SYU and SYL are coupled to one end and the other end of each conductor 22, respectively. During data read from the selected memory cell MC in contact with a portion of the conductor 21 that is far from the switch SX, both the switches SYU and SYL coupled to the conductor 22 coupled to the selected memory cell MC are maintained on. Because of this, the resistance between the switch SX coupled to the selected memory cell MC via the conductor 21 and the switches SYU and SYL coupled to the selected memory cell MC via the conductor 22 is lower than a case where only one of the switches SYU and SYL is used. Therefore, in a case where the resistance due to the conductor 21 is large because the memory cell MC is far from the switch SX, it is possible to suppress the peak of the cell current without excessively increasing the resistance due to the conductor 22. As a result, variations in the cell current due to variations in the resistance of the current path are suppressed.

In addition, according to the second embodiment, as in the first embodiment, during data read from the selected memory cell MC in contact with a portion of the conductor 21 that is not far from the switch SX, of the switches SYU and SYL coupled to the selected bit line BL, one farther from the selected memory cell MC is turned on and the other is maintained off. Thus, in the case of the data read from the selected memory cell MC in contact with the portion of the conductor 21 that is not far from the switch SX, the same advantages as those of the first embodiment can be obtained. Therefore, according to the second embodiment, variations in the cell current depending on the position of the memory cell MC are smaller than variations in the first embodiment.

### 3. Third Embodiment

A third embodiment relates to data write operation. The third embodiment can be additionally implemented to the first or second embodiment.

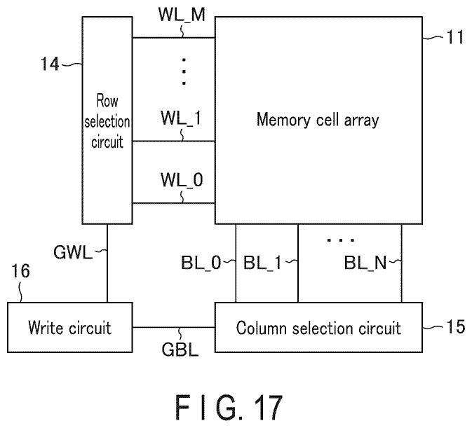

FIG. 17 illustrates functional blocks and components of a part of a memory device of the third embodiment. As illustrated in FIG. 17, the write circuit 16 is coupled to the global word line GWL and the global bit line GBL.

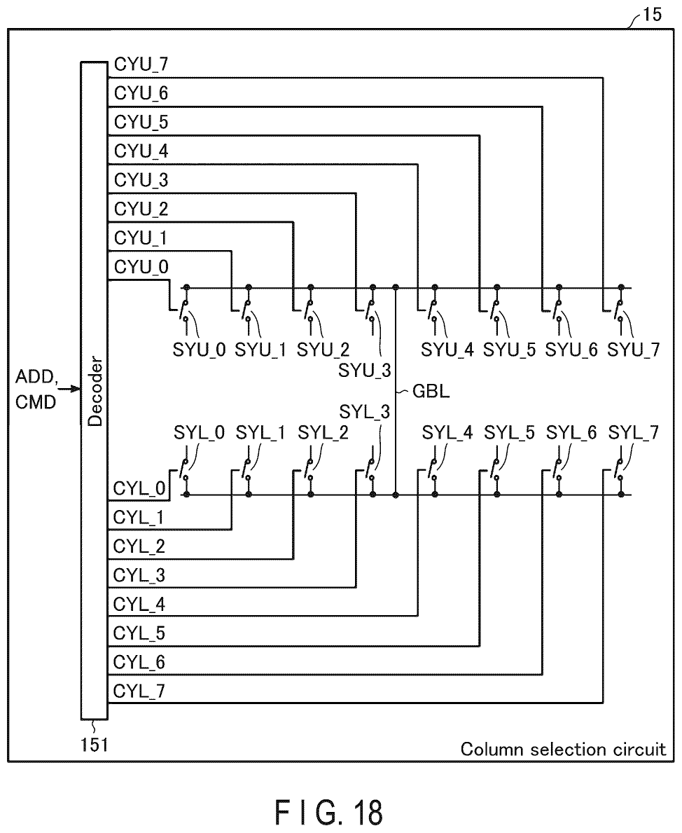

FIG. 18 illustrates components of a column selection circuit of the memory device of the third embodiment. As illustrated in FIG. 18, the decoder 151 further receives the command CMD. As a result of decoding of the address information ADD and based on the command CMD, the decoder 151 outputs signals CYL_0 to CYL_7 and CYU_0 to CYU_7 having logic levels based on the result of decoding.

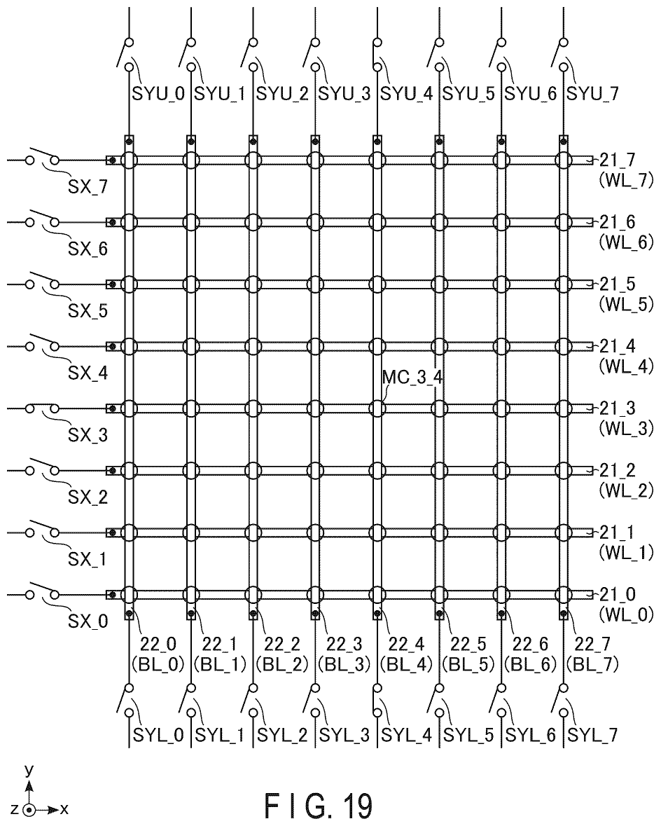

FIG. 19 illustrates an example of a state during an operation of the memory device of the third embodiment. FIG. 19 illustrates, as an example, a state during which data is being written to the memory cell MC_3_4. As in the first and second embodiments, the switch SX coupled to the selected word line WL is maintained on, and the switch SX coupled to the non-selected word line WL is maintained off.

While data is written to the selected memory cell MC to which data is to be written, the column selection circuit 15 maintains both of two switches SYL and SYU coupled to the selected bit line BL on. That is, when the decoder 151 of the column selection circuit 15 receives a command CMD that instructs decoder 151 to perform data write, the decoder 151 maintains both of the two switches SYL and SYU coupled to the selected bit line BL on. In the example illustrated in FIG. 19, the switches SYL_4 and SYU_4 are maintained on during the data write. During the data write, the two switches SYL and SYU coupled to each non-selected bit line BL are maintained off. In a state where the switches SYU and SYL are maintained on or off in this manner, the write circuit 16 applies a voltage or a current to the global word line GWL and the global bit line GBL so that a cell current in a direction based on data to be written to the selected memory cell MC flows through the selected memory cell MC.

According to the third embodiment, as in the first and second embodiments, the switches SYU and SYL are coupled to one end and the other end of each conductor 22, respectively. During data write, both the switches SYU and SYL coupled to the conductor 22 coupled to the selected memory cell MC are maintained on. Because of this, the resistance between the switch SX coupled to the selected memory cell MC via the conductor 21 and the switches SYU and SYL coupled to the selected memory cell MC via the conductor 22 is lower than a case where only one of the switches SYU and SYL is used. Therefore, the resistance of the current path is suppressed, and a large cell current can flow through such a current path. As a result, a reduction in the cell current or an increase of write time due to the resistance of the current path is suppressed.

### 4. Fourth Embodiment

The fourth embodiment is different from the first and second embodiments in terms of classification of the memory cells MC.

### 4.1. Configuration

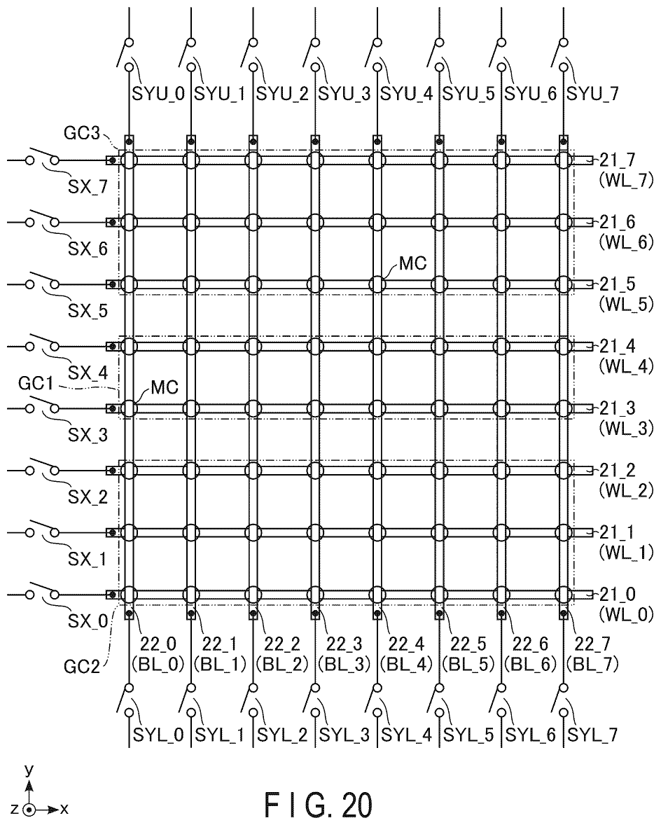

FIG. 20 illustrates an example of classification of the memory cells of a memory device of a fourth embodiment. The memory cells MC are classified into three groups. As an example, assume that, with respect to the center of the conductors 22 on the y axis, R conductors 21 are positioned in the +Y direction and R conductors 21 are positioned in the −Y direction, and the following description is based on the example. For all cases where α is (M+1)/2−R or more and (M+1)/2+R−1 or less, a memory cell MC coupled to a conductor 21_α belongs to a group GC1. In other words, for all cases where β is 0 or more and N or less, in a case where both a distance of a current path from a certain memory cell MC to the switch SYL_β via the current path including a part of the conductor 22_β and a distance of a current path from the memory cell MC to the switch SYU_β via the current path including a part of the conductor 22_β have a certain value or more, the memory cell MC belongs to the group GC1. Based on the current example, R is 1, the memory cell MC coupled to any of the conductor 21_3 and the conductor 21_4 belongs to the group GC1.

For all cases where α is 0 or more and less than (M+1)/2−R, a memory cell MC coupled to the conductor 21_α belongs to a group GC2. In other words, for all cases where β is 0 or more and N or less, in a case where a distance of a current path from a certain memory cell MC to the switch SYL_β via the current path including a part of the conductor 22_β is shorter than a distance of a current path from a memory cell MC which is on the same conductor 22_β and belongs to the group GC1 to the switch SYL_β via the current path including a part of the conductor 22_β, the memory cell MC belongs to the group GC2. Based on the current example, the memory cell MC coupled to any of the conductors 21_0, 21_1, and 21_2 belongs to the group GC2.

For all cases where α is (M+1)/2+R−1 or more and M or less, a memory cell MC coupled to the conductor 21_α belongs to a group GC3. In other words, for all cases where β is 0 or more and N or less, in a case where a distance of a current path from a certain memory cell MC to the switch SYU_β via the current path including a part of the conductor 22_β is shorter than a distance of a current path from the memory cell MC which is on the same conductor 22_β and belongs to the group GC1 to the switch SYU_β via the current path including a part of the conductor 22_β, the memory cell MC belongs to the group GC3. Based on the current example, the memory cell MC coupled to any of the conductors 21_5, 21_6, and 21_7 belongs to the group GC3.

### 4.2 Operation

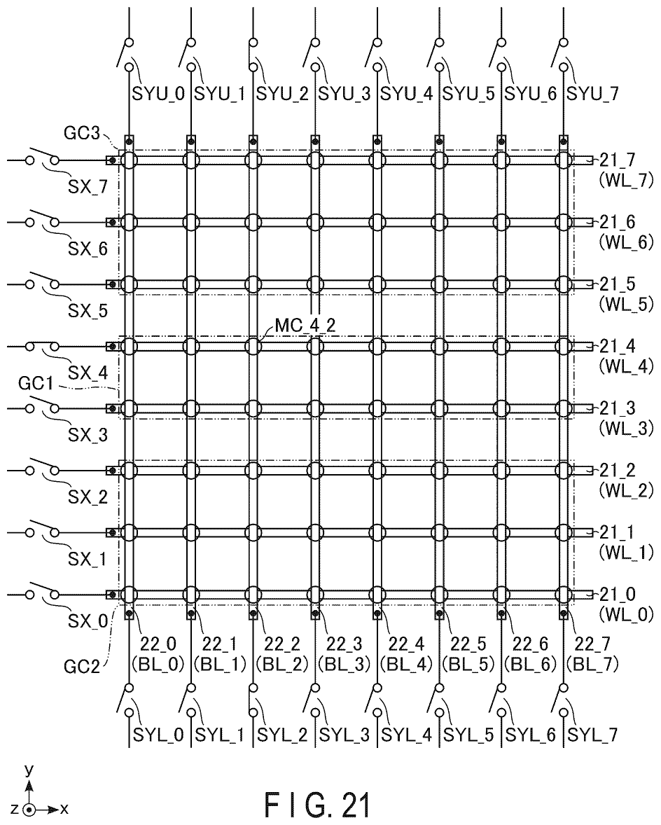

FIG. 21 illustrates an example of a state during an operation of the memory device of the fourth embodiment. FIG. 21 illustrates a state during which data is being read from a memory cell MC belonging to the group GC1, and, as an example, illustrates a state during which data is being read from the memory cell MC_4_2.

The switch SX coupled to the selected word line WL is maintained on, and the switch SX coupled to the non-selected word line WL is maintained off. In the example of FIG. 21, the switch SX_4 is maintained on, and all of the switches SX except for the switch SX_4 are maintained off. In a case where a data read target memory cell MC belongs to the group GC1, both the switches SYL and SYU coupled to the selected bit line BL are maintained on. The switches SYL and SYU coupled to the non-selected bit line BL are maintained off. In the example of FIG. 21, the switch SYL_2 and the switch SYU_2 are maintained on, and all of the switches SYL except for the switch SYL_2 and all of the switches SYU except for the switch SYU_2 are maintained off.

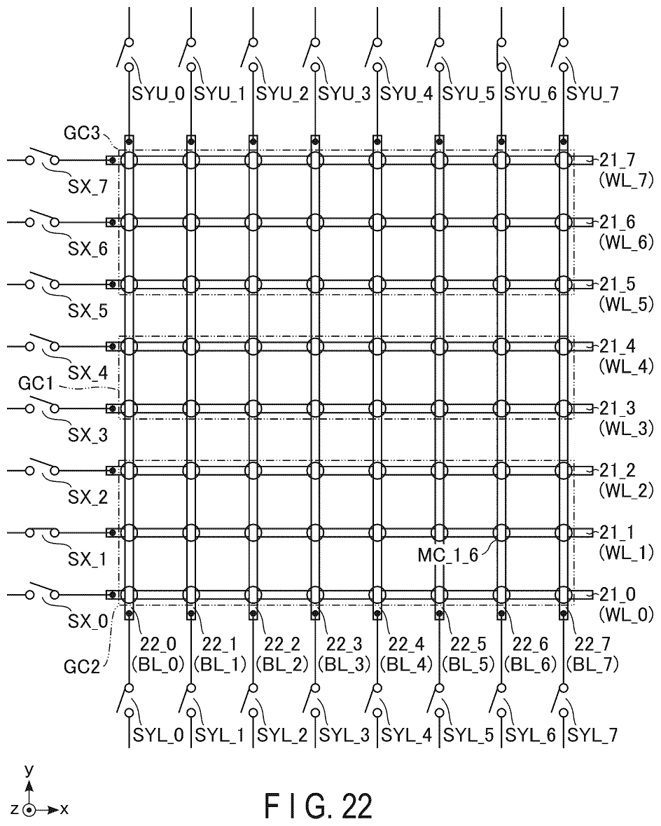

FIG. 22 illustrates an example of a state during an operation of the memory device of the fourth embodiment. FIG. 22 illustrates a state during which data is being read from a memory cell MC belonging to the group GC2, and, as an example, illustrates a state during which data is being read from the memory cell MC_1_6.

The switch SX coupled to the selected word line WL is maintained on, and the switch SX coupled to the non-selected word line WL is maintained off. In the example of FIG. 22, the switch SX_1 is maintained on, and all of the switches SX except for the switch SX_1 are maintained off.

In a case where a data read target memory cell MC belongs to the group GC2, of the switches SYL and SYU coupled to the selected bit line BL, the switch SYU is maintained on and the switch SYL is maintained off. The switches SYL and SYU coupled to the non-selected bit line BL are maintained off. In the example of FIG. 22, the switch SYU_6 is maintained on, and all of the switches SYU except for the switch SYU_6 and all of the switches SYL are maintained off.

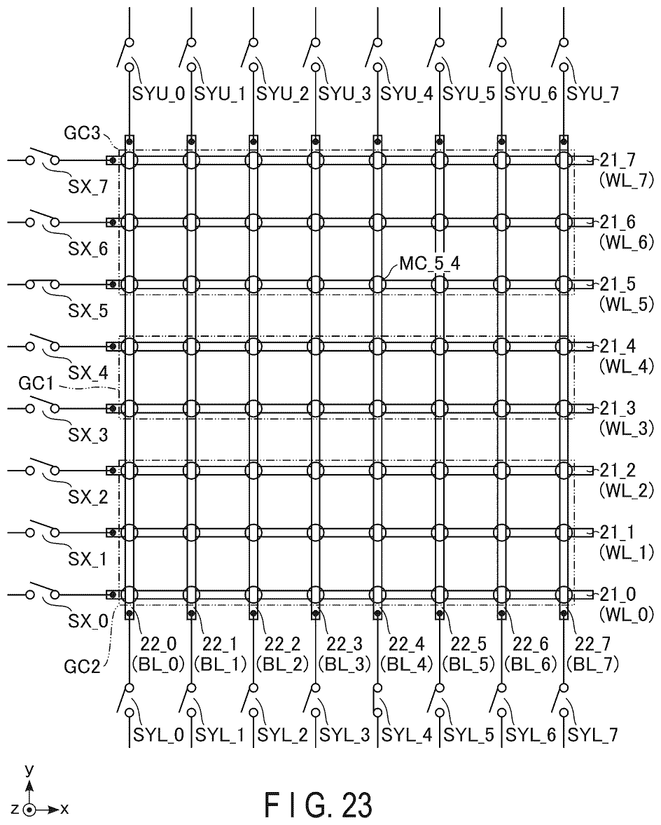

FIG. 23 illustrates an example of a state during an operation of the memory device of the fourth embodiment. FIG. 23 illustrates a state during which data is being read from a memory cell MC belonging to the group GC3, and, as an example, illustrates a state during which data is being read from the memory cell MC_5_4.

The switch SX coupled to the selected word line WL is maintained on, and the switch SX coupled to the non-selected word line WL is maintained off. In the example of FIG. 23, the switch SX_5 is maintained on, and all of the switches SX except for the switch SX_5 are maintained off.

In a case where a data read target memory cell MC belongs to the group GC3, of the switches SYL and SYU coupled to the selected bit line BL, the switch SYL is maintained on and the switch SYU is maintained off. The switches SYL and SYU coupled to the non-selected bit line BL are maintained off. In the example of FIG. 23, the switch SYL_4 is maintained on, and all of the switches SYL except for the switch SYL_4 and all of the switches SYU are maintained off.

According to the fourth embodiment, as in the first embodiment, the switches SYU and SYL are coupled to one end and the other end of each conductor 22 (or bit line BL), respectively, and during data read, of the switches SYU and SYL coupled to the selected bit line BL, one farther from the selected memory cell MC is maintained on, and the other is maintained off. Thus, the same advantages as those of the first embodiment can be obtained.

Furthermore, during data read from the selected memory cell MC in contact with a portion of the conductor 22 that is far from both the switches SYU and SYL, both the switches SYU and SYL coupled to the selected bit line BL are maintained on. Therefore, a resistance of a current path during data read from the selected memory cell MC far from both the switches SYU and SYL is small.

### 5. Modification

The above description is based on an example in which the boundary between the group G1 and the group G2 or the boundary between the group GB2 and the group GB3 is located at the center of the conductor 22, that is, an example in which the number of memory cells MC arranged along the y axis in the group G1 or the group GB2 is equal to the number of memory cells MC arranged along the y axis in the group G2 or the group GB3. The number of memory cells MC arranged along the y axis in the group G1 or the group GB2 may be different from the number of memory cells MC arranged along the y axis in the group G2 or the group GB3.

The above description is based on an example in which the number of memory cells MC along the y-axis in the group GC2 equals the number of memory cells MC along the y-axis in the group GC3. The number of memory cells MC along the y-axis in the group GC2 may differ from the number of memory cells MC along the y-axis in the group GC3.

The above description is based on an example in which the fourth embodiment is based on the first embodiment. The fourth embodiment can be combined with the second embodiment.

The first, second, third, and fourth embodiments are based on an example in which the switch SX is coupled only to one end of the conductor 21 and the switches SYL and SYU are coupled to both ends of the conductor 22. A switch SY (for example, corresponding to the switch SYL) may be coupled only to one end (for example, the end on the −Y direction side) of the conductor 22, and switches SXL and SXR may be coupled to both ends of the conductor 21. In this case, in the first or third embodiment, the group G1 includes the memory cell MC closer to the switch SXL, and the group G2 includes the memory cell MC closer to the switch SXR. In the second embodiment, the group GB1 includes the memory cell MC farther from the switch SY, the group GB2 includes the memory cell MC close to the switch SY and close to the switch SXL, and the group GB3 includes the memory cell MC close to the switch SY and close to the switch SXR. In the fourth embodiment, the group GC1 includes the memory cell MC far from both the switch SXL and SXR to some extent, the group GC2 includes the memory cell MC closer to the switch SXL than the memory cell MC in the group GC1, and the group GC3 includes the memory cell MC closer to the switch SXR than the memory cell MC in the group GC1. Regarding the operation, the description about the switches SYL and SYU in the descriptions of the first, second, third, and fourth embodiments is replaced with that about the switches SXL and SXR, and the description about the switch SX is replaced with that about the switch SY.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first conductor;
a second conductor located farther in a first direction than the first conductor;
a third conductor that extends in the first direction, intersects with the first conductor and the second conductor, and has a first end and a second end, the first end being located farther in the first direction than the second end;
a first memory cell coupled to the first conductor and the third conductor;
a second memory cell coupled to the second conductor and the third conductor;
a first switch coupled to the first end of the third conductor; and
a second switch coupled to the second end of the third conductor,
wherein, in a case of data read from the first memory cell, the first switch is maintained on and the second switch is maintained off, and
in a case of data read from the second memory cell, the second switch is maintained on and the first switch is maintained off.

2. The memory device according to claim 1, wherein
the first conductor and the second conductor extend in a second direction,
the first conductor has a third end on a side of the second direction,
the second conductor has a fourth end on the side of the second direction,
the memory device further comprises a third switch coupled to the third end of the first conductor and a fourth switch coupled to the fourth end of the second conductor,
in the case of data read from the first memory cell, the third switch is maintained on, and
in the case of data read from the second memory cell, the fourth switch is maintained on.

3. The memory device according to claim 2, further comprising
a first interconnect,
wherein the first switch is coupled between the first end of the third conductor and the first interconnect, and
the second switch is coupled between the second end of the third conductor and the first interconnect.

4. The memory device according to claim 3, further comprising:
a second interconnect,
wherein the third switch is coupled between the third end of the first conductor and the second interconnect,
the fourth switch is coupled between the fourth end of the second conductor and the second interconnect,
one of the first interconnect and the second interconnect is coupled to a node of a first voltage and a sense amplifier circuit, and
the other of the first interconnect and the second interconnect is coupled to a node of a second voltage lower than the first voltage.

5. The memory device according to claim 1, wherein
the first conductor is located closer to the second end of the third conductor than to the first end of the third conductor, and
the second conductor is located closer to the first end of the third conductor than to the second end of the third conductor.

6. The memory device according to claim 5, further comprising:
a memory cell array including a plurality of memory cells including the first memory cell and the second memory cell,
wherein the first switch is located farther in the first direction than the memory cell array, and
the second switch is located farther in a direction opposite to the first direction than the memory cell array.

7. The memory device according to claim 4, further comprising:
a memory cell array including a plurality of memory cells including the first memory cell and the second memory cell,
wherein the first switch is located farther in the first direction than the memory cell array, and
the second switch is located farther in a direction opposite to the first direction than the memory cell array.

8. The memory device according to claim 2, wherein
the first conductor is located closer to the second end of the third conductor than to the first end of the third conductor, and
the second conductor is located closer to the first end of the third conductor than to the second end of the third conductor.

9. The memory device according to claim 8, further comprising:
a memory cell array including a plurality of memory cells including the first memory cell and the second memory cell,
wherein the first switch is located farther in the first direction than the memory cell array, and
the second switch is located farther in a direction opposite to the first direction than the memory cell array.

10. The memory device according to claim 1, further comprising:
a memory cell array including a plurality of memory cells including the first memory cell and the second memory cell,
wherein the first switch is located farther in the first direction than the memory cell array, and
the second switch is located farther in a direction opposite to the first direction than the memory cell array.

11. The memory device according to claim 1, further comprising:
a fourth conductor that extends in the first direction, is located farther in a direction opposite to the second direction than the third conductor, intersects with the first conductor and the second conductor, and has a fifth end and a sixth end, the fifth end being located farther in the first direction than the sixth end;
a third memory cell coupled to one of the first conductor and the second conductor, and coupled to the fourth conductor;
a fifth switch coupled to the fifth end of the fourth conductor; and
a sixth switch coupled to the sixth end of the fourth conductor,
wherein, in a case of data read from the third memory cell, the fifth switch and the sixth switch are maintained on.

12. The memory device according to claim 11, wherein
the first conductor and the second conductor extend in a second direction,
the first conductor has a third end on a side of the second direction,
the second conductor has a fourth end on the side of the second direction,
the memory device further comprises a third switch coupled to the third end of the first conductor and a fourth switch coupled to the fourth end of the second conductor,
in the case of data read from the first memory cell, the third switch is maintained on, and
in the case of data read from the second memory cell, the fourth switch is maintained on.

13. The memory device according to claim 12, further comprising:
a first interconnect,
wherein the first switch is coupled between the first end of the third conductor and the first interconnect,
the second switch is coupled between the second end of the third conductor and the first interconnect,
the fifth switch is coupled between the fifth end of the fourth conductor and the first interconnect, and
the sixth switch is coupled between the sixth end of the fourth conductor and the first interconnect.

14. The memory device according to claim 13, further comprising:
a second interconnect,
wherein the third switch is coupled between the third end of the first conductor and the second interconnect,
the fourth switch is coupled between the fourth end of the second conductor and the second interconnect,
one of the first interconnect and the second interconnect is coupled to a node of a first voltage and a sense amplifier circuit, and
the other of the first interconnect and the second interconnect is coupled to a node of a second voltage lower than the first voltage.

15. The memory device according to claim 11, wherein
the first conductor is located closer to the second end of the third conductor than to the first end of the third conductor, and
the second conductor is located closer to the first end of the third conductor than to the second end of the third conductor.

16. The memory device according to claim 12, wherein
the first conductor is located closer to the second end of the third conductor than to the first end of the third conductor, and
the second conductor is located closer to the first end of the third conductor than to the second end of the third conductor.

17. The memory device according to claim 1, wherein
each of the first memory cell and the second memory cell includes a first ferromagnetic layer, a second ferromagnetic layer, and an insulating layer between the first ferromagnetic layer and the second ferromagnetic layer.

18. A memory device comprising:
a first conductor;
a second conductor that intersects with the first conductor, extends in a first direction, has a first end and a second end, the first end being located farther in the first direction than the second end;
a memory cell coupled to the first conductor and the second conductor;
a first switch coupled to the first end of the second conductor; and
a second switch coupled to the second end of the second conductor,
wherein, in a case of data write to the memory cell, the first switch and the second switch are maintained on.

19. The memory device according to claim 18, wherein
the first conductor extends in a second direction,
the first conductor has a third end on a second direction side,
the memory device further comprises a third switch coupled to the third end of the first conductor, and,
in the case of data write to the memory cell, the third switch is maintained on.

20. The memory device according to claim 1, further comprsigin:
a fifth conductor located farther in the first direction than the first conductor and farther in a direction opposite the first direction than the second direction, and intersecting with the third conductor, and
a fourth memory cell coupled to the fifth conductor and the third conductor,
wherein in a case of data read from the fourth memory cell, the first swtich and the second switch are maintained on.

21. The memory device according to claim 20, wherein
the first conductor is located closer to the second end of the third conductor than to the first end of the third conductor,
the second conductor is located closer to the first end of the third conductor than to the second end of the third conductor, and
the fifth conductor is located farther from the second end of the third conductor than the first conductor and farther from the first end of the third conductor than the second conductor.
